(19) United States
(12) Patent Application Publication
(10) Pub. No.: US 2023/0028925 A1
(43) Pub. Date: Jan. 26, 2023

(54) MULTILAYER PIEZOELECTRIC SUBSTRATE DEVICE WITH REDUCED PIEZOELECTRIC MATERIAL CUT ANGLE

(71) Applicant: Skyworks SOLUTIONS, INC., Irvine, CA (US)

(72) Inventor: Kyohei Kobayashi, Otsu-Shi (JP)

(21) Appl. No.: 17/810,918

(22) Filed: Jul. 6, 2022

Related U.S. Application Data
(60) Provisional application No. 63/225,086, filed on Jul. 23, 2021.

(51) Int. Cl. H03H 9/02; H03H 9/64

(52) U.S. Cl. CPC H03H 9/02574; H03H 9/02559; H03H 9/02834; H03H 9/6453; H03H 9/25

(57) ABSTRACT

A surface acoustic wave resonator comprises a multi-layer piezoelectric substrate including a carrier substrate, a layer of a first dielectric material disposed on a front side of the carrier substrate, and a layer of piezoelectric material disposed on a front side of the layer of the first dielectric material, the piezoelectric material having a cut angle θ of from about 12 degrees to about 25 degrees to suppress bulk leakage and improve gamma, and interdigital transducer electrodes disposed on a front side of the layer of piezoelectric material.

### CROSS-REFERENCE TO RELATED APPLICATIONS

This application claims priority under 35 U.S.C. § 119(e) to U.S. Provisional patent application Ser. No. 63/225,086, titled “MULTILAYER PIEZOELECTRIC SUBSTRATE DEVICE WITH REDUCED PIEZOELECTRIC MATERIAL CUT ANGLE,” filed Jul. 23, 2021, the entire contents of which is incorporated herein by reference for all purposes.

### BACKGROUND

### Technical Field

Embodiments of this disclosure relate to acoustic wave devices and filters and to methods and structures for increasing the coupling coefficient and reducing gamma parameters in same.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front end of a mobile telephone can include acoustic wave filters. Two acoustic wave filters can be arranged as a duplexer or a diplexer.

### SUMMARY

In accordance with one aspect, there is provided a surface acoustic wave resonator. The surface acoustic wave resonator comprises a multi-layer piezoelectric substrate including a carrier substrate, a layer of a first dielectric material disposed on a front side of the carrier substrate, and a layer of piezoelectric material disposed on a front side of the layer of the first dielectric material, the piezoelectric material having a cut angle θ of from about 12 degrees to about 25 degrees to suppress bulk leakage and improve gamma, and interdigital transducer electrodes disposed on a front side of the layer of piezoelectric material.

In some embodiments, the surface acoustic wave resonator further comprises a layer of a second dielectric material disposed on the layer of piezoelectric material and the interdigital transducer electrodes.

In some embodiments, the first dielectric material comprises silicon dioxide.

In some embodiments, the second dielectric material comprises silicon dioxide.

In some embodiments, the layer of piezoelectric material has a thickness of from about 0.1λ to about 0.2λ.

In some embodiments, the layer of the first dielectric material has a thickness of from about 0.05λ to about 0.40λ.

In some embodiments, the surface acoustic wave resonator exhibits a temperature coefficient of frequency at its resonant frequency of greater than about −19 ppm/° K.

In some embodiments, the surface acoustic wave resonator exhibits an electromagnetic coupling coefficient of at least about 15.5.

In some embodiments, the surface acoustic wave resonator exhibits a quality factor at its resonance frequency of at least about 1450.

In some embodiments, the layer of piezoelectric material is formed of lithium niobate.

In some embodiments, the surface acoustic wave resonator is included in a filter.

In some embodiments, the filter is included in a radio frequency device module.

In some embodiments, the radio frequency device module is included in a radio frequency device.

In accordance with another aspect, there is provided a method of forming a surface acoustic wave resonator. The method comprises forming interdigital transducer electrodes on a multi-layer piezoelectric substrate including a carrier substrate, a layer of a first dielectric material disposed on a front side of the carrier substrate, and a layer of lithium niobate disposed on a front side of the layer of the first dielectric material, the piezoelectric material having a cut angle θ of from about 12 degrees to about 25 degrees to suppress bulk leakage and improve gamma.

In some embodiments, the method further comprises forming a layer of a second dielectric material on the interdigital transducer electrodes and the layer of piezoelectric material.

In some embodiments, the layer of the first dielectric material is formed with a thickness of from about 0.1λ to about 0.2λ.

In some embodiments, the layer of piezoelectric material is formed with a thickness of from about 0.05λ to about 0.30λ In some embodiments, the method further comprises forming a radio frequency filter including the surface acoustic wave resonator.

In some embodiments, the method further comprises forming a radio frequency device module including the radio frequency filter.

In some embodiments, the method further comprises forming a radio frequency electronic device including the radio frequency device module.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2A is a cross-sectional view of a portion of a surface acoustic wave resonator having a piezoelectric substrate;

FIG. 2B is a cross-sectional view of a portion of a surface acoustic wave resonator having a multi-layer piezoelectric substrate;

FIG. 3 is a table of parameters and properties of surface acoustic wave resonators formed from different types of substrates;

FIG. 4A is a chart of simulated spurious signal levels as a function of lithium niobate cut angle and silicon dioxide thickness for acoustic wave resonators formed with one type of substrate;

FIG. 4B is a chart of simulated spurious signal levels as a function of lithium niobate cut angle and silicon dioxide thickness for acoustic wave resonators formed with another type of substrate;

FIG. 4C is a chart of simulated spurious signal levels as a function of lithium niobate cut angle and thickness for some embodiments of acoustic wave resonators disclosed herein;

FIG. 5A is a chart of admittance and real admittance versus frequency for shunt resonators formed with the different substrates described in FIG. 3;

FIG. 5B is a chart of admittance and real admittance versus frequency for series resonators formed with the different substrates described in FIG. 3;

FIG. 6A is a chart of attenuation versus frequency for unloaded ladder filters formed of acoustic wave resonators having two different types of substrate;

FIG. 6B is a chart of carrier aggregation rejection versus frequency for loaded ladder filters connected to an antenna switch and formed of resonators having two different types of substrate;

FIG. 6C is a Smith chart illustrating reflection characteristics of the antenna terminal and reflection characteristics from filter output terminal for ladder filters formed of acoustic wave resonators having two different types of substrate;

FIG. 6D is a chart illustrating maximum gain versus frequency for unloaded ladder filters formed of resonators having two different types of substrate;

FIG. 6E is a chart illustrating the passband for loaded ladder filters connected to an antenna switch and formed of resonators having two different types of substrate;

FIG. 6F is a chart illustrating the passband for loaded ladder filters connected to an antenna switch and low noise amplifier and formed of resonators having two different types of substrate;

FIG. 6G is a chart illustrating gamma and phase shift versus frequency for unloaded ladder filters formed of resonators having two different types of substrate;

FIG. 6H is a chart illustrating the S11 reflectance parameter versus frequency for loaded ladder filters connected to an antenna switch and low noise amplifier and formed of resonators having two different types of substrate;

FIG. 6I is a chart illustrating noise figure versus frequency for unloaded ladder filters formed of resonators having two different types of substrate;

FIG. 7A is a chart illustrating loading loss versus frequency in the B3 transmission band for ladder filters formed of resonators having two different types of substrate;

FIG. 7B is a chart illustrating loading loss versus frequency in the B3 reception band for ladder filters formed of resonators having two different types of substrate;

FIG. 7C is a chart illustrating loading loss versus frequency in the B1 transmission band for ladder filters formed of resonators having two different types of substrate;

FIG. 7D is a chart illustrating loading loss versus frequency in the B1 reception band for ladder filters formed of resonators having two different types of substrate;

FIG. 7E is a chart illustrating loading loss versus frequency in the B32 band for ladder filters formed of resonators having two different types of substrate;

FIG. 7F is a chart illustrating loading loss versus frequency in the B40 band for ladder filters formed of resonators having two different types of substrate;

FIG. 7G is a chart illustrating loading loss versus frequency in the B7 transmission band for ladder filters formed of resonators having two different types of substrate;

FIG. 7H is a chart illustrating loading loss versus frequency in the B7 reception band for ladder filters formed of resonators having two different types of substrate;

FIG. 8A is a chart of attenuation versus frequency for unloaded ladder filters formed of acoustic wave resonators having two different types of substrate;

FIG. 8B is a chart of carrier aggregation rejection versus frequency for loaded ladder filters connected to an antenna switch and formed of resonators having two different types of substrate;

FIG. 8C is a Smith chart illustrating reflection characteristics of the antenna terminal and reflection characteristics from filter output terminal for ladder filters formed of acoustic wave resonators having two different types of substrate;

FIG. 8D is a chart illustrating maximum gain versus frequency for unloaded ladder filters formed of resonators having two different types of substrate;

FIG. 8E is a chart illustrating the passband for loaded ladder filters connected to an antenna switch and formed of resonators having two different types of substrate;

FIG. 8F is a chart illustrating the passband for loaded ladder filters connected to an antenna switch and low noise amplifier and formed of resonators having two different types of substrate;

FIG. 8G is a chart illustrating gamma and phase shift versus frequency for unloaded ladder filters formed of resonators having two different types of substrate;

FIG. 8H is a chart illustrating the S11 reflectance parameter versus frequency for loaded ladder filters connected to an antenna switch and low noise amplifier and formed of resonators having two different types of substrate;

FIG. 8I is a chart illustrating noise figure versus frequency for unloaded ladder filters formed of resonators having two different types of substrate;

FIG. 9A is a chart illustrating loading loss versus frequency in the B3 transmission band for ladder filters formed of resonators having two different types of substrate;

FIG. 9B is a chart illustrating loading loss versus frequency in the B3 reception band for ladder filters formed of resonators having two different types of substrate;

FIG. 9C is a chart illustrating loading loss versus frequency in the B1 transmission band for ladder filters formed of resonators having two different types of substrate;

FIG. 9D is a chart illustrating loading loss versus frequency in the B1 reception band for ladder filters formed of resonators having two different types of substrate;

FIG. 9E is a chart illustrating loading loss versus frequency in the B32 band for ladder filters formed of resonators having two different types of substrate;

FIG. 9F is a chart illustrating loading loss versus frequency in the B40 band for ladder filters formed of resonators having two different types of substrate;

FIG. 9G is a chart illustrating loading loss versus frequency in the B7 transmission band for ladder filters formed of resonators having two different types of substrate;

FIG. 9H is a chart illustrating loading loss versus frequency in the B7 reception band for ladder filters formed of resonators having two different types of substrate;

FIG. 10 is a schematic diagram of a radio frequency ladder filter;

FIG. 11 is a block diagram of one example of a filter module that can include one or more acoustic wave elements according to aspects of the present disclosure;

FIG. 12 is a block diagram of one example of a front-end module that can include one or more filter modules according to aspects of the present disclosure; and

FIG. 13 is a block diagram of one example of a wireless device including the front-end module of FIG. 12.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

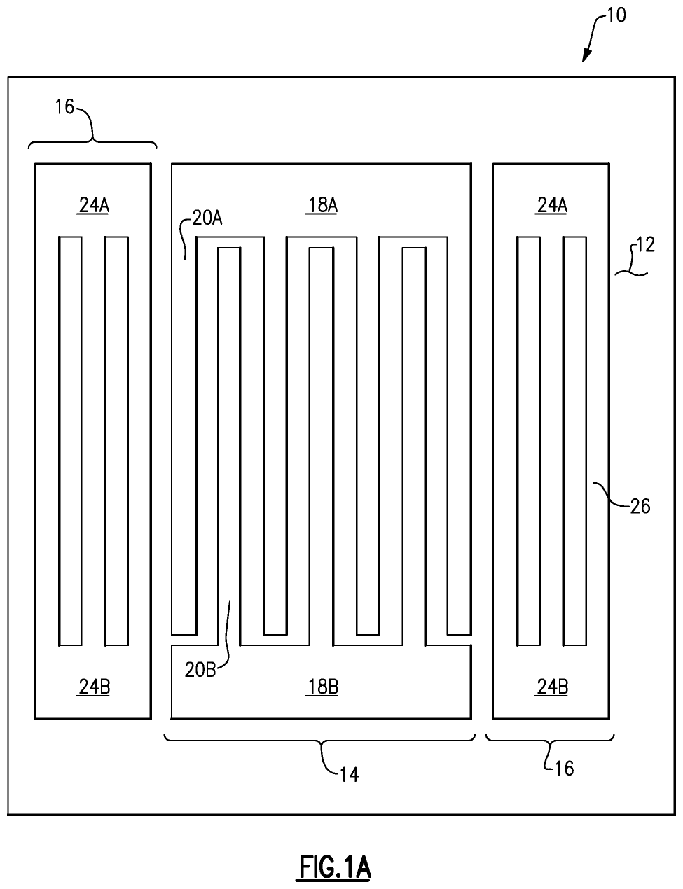

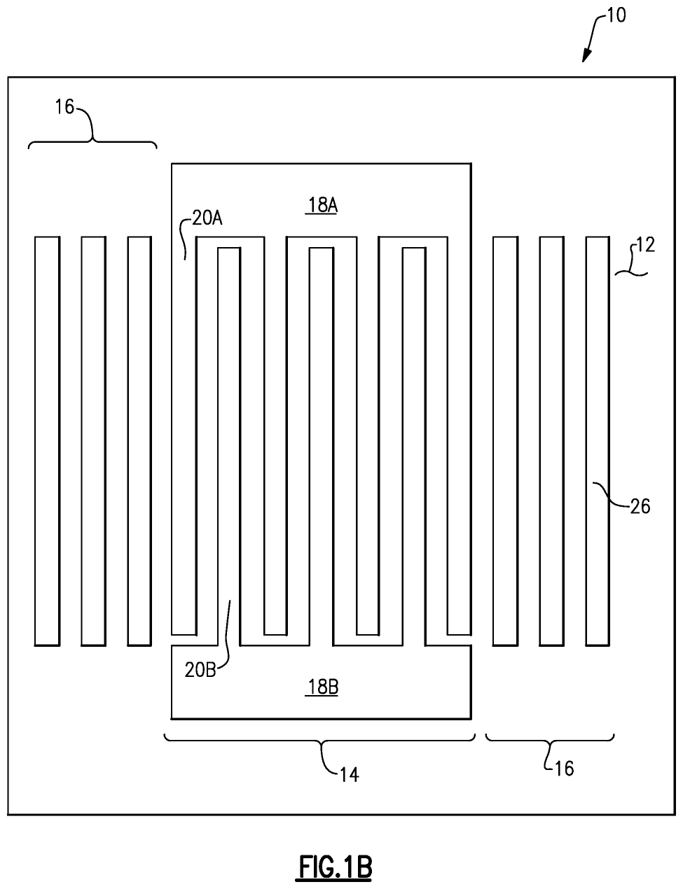

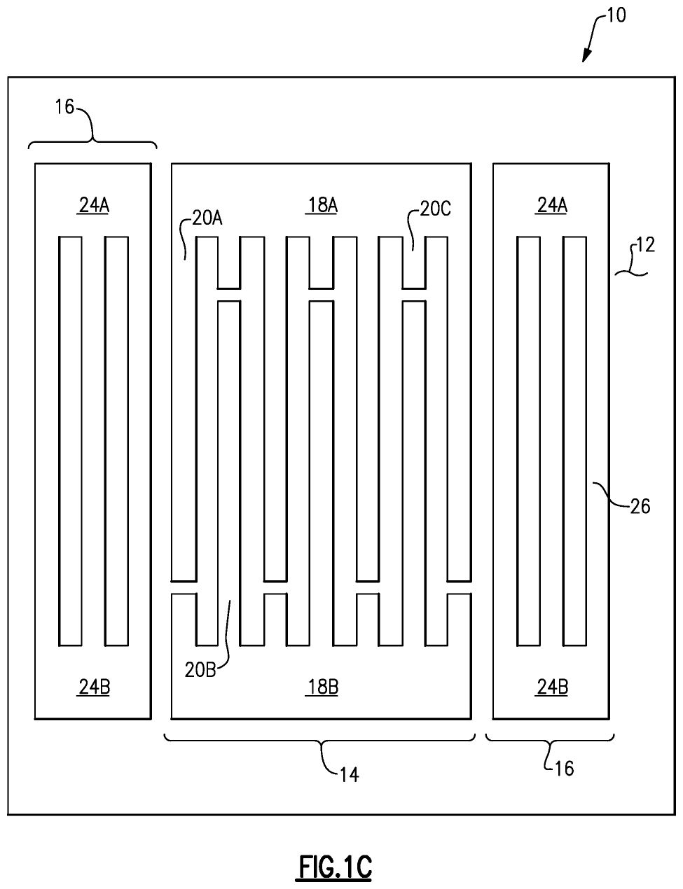

FIG. 1A is a plan view of a surface acoustic wave (SAW) resonator 10 such as might be used in a SAW filter, duplexer, diplexer, balun, etc.

Acoustic wave resonator 10 is formed on a piezoelectric substrate, for example, a lithium tantalate (LiTaO₃) or lithium niobate (LiNbO₃) substrate 12 and includes interdigital transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes. The IDT electrodes 14 include a first busbar electrode 18A and a second busbar electrode 18B facing first busbar electrode 18A. The busbar electrodes 18A, 18B may be referred to herein together as busbar electrode 18. The IDT electrodes 14 further include first electrode fingers 20A extending from the first busbar electrode 18A toward the second busbar electrode 18B, and second electrode fingers 20B extending from the second busbar electrode 18B toward the first busbar electrode 18A.

The reflector electrodes 16 (also referred to as reflector gratings) each include a first reflector busbar electrode 24A and a second reflector busbar electrode 24B (collectively referred to herein as reflector busbar electrode 24) and reflector fingers 26 extending between and electrically coupling the first busbar electrode 24A and the second busbar electrode 24B.

In other embodiments disclosed herein, as illustrated in FIG. 1B, the reflector busbar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite busbar electrode 18A, 18B than the respective electrode finger 20A, 20B with which it is aligned.

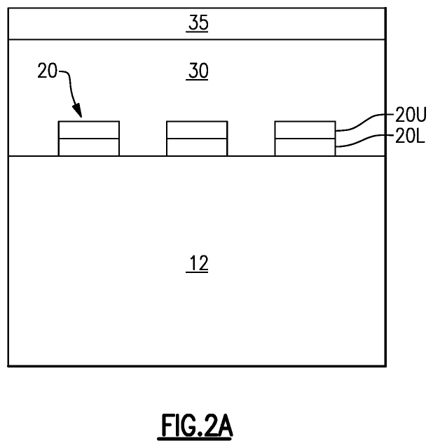

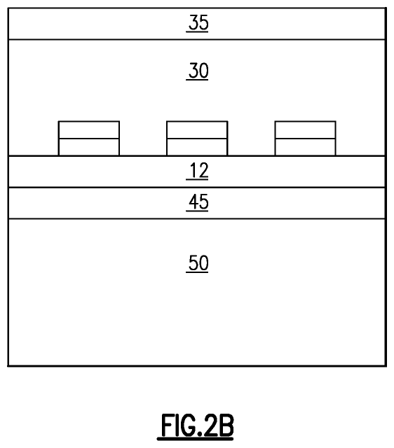

FIG. 2A is a partial cross-sectional view of a surface acoustic wave resonator such as any of the resonators illustrated in FIGS. 1A-1C. The substrate 12 is formed of bulk lithium niobate. The cut angle θ of the lithium niobate may be 127.5 degrees. The IDT electrode fingers 20 may be formed as a dual layer structure including an upper layer 20U of aluminum deposited on a lower layer 20L of molybdenum. A layer of silicon dioxide 30 may be disposed over the substrate 12 and IDT electrode fingers. In some embodiments a layer of silicon nitride 35 is disposed on top of the layer of silicon dioxide 30.

With migration of cellular telephones to the fifth-generation (5G) technology standard for broadband cellular networks, it has become desirable to provide acoustic wave filters with wider bandwidth, higher coupling factor, and lower gamma than might be achieved with some embodiments of the substrate structure as illustrated in FIG. 2A. Reducing the cut angle of the lithium niobate piezoelectric material used in the resonator substrate, for example, to a cut angle θ of between about −4 degrees and about −5 degrees, about −4 degrees, between about 18 degrees and about 23 degrees, or about 20 degrees may increase the coupling coefficient of the resonator, but this tends to also reduce performance by increasing the gamma coefficient, a measure of power reflection as compared to power input into a resonator.

Simulations have suggested that by changing the substrate to a laminated structure of lithium niobate/silicon dioxide/silicon, bulk leakage can be suppressed and better gamma can be obtained while the temperature coefficient of frequency (TCF) and quality factor Q at the resonance frequency of the resonator may be maintained at acceptable levels for acoustic wave resonators using lithium niobate with low cut angles.

An example of a multilayer piezoelectric substrate including a laminated structure of lithium niobate 12, silicon dioxide 45, and silicon 50 is illustrated in FIG. 2B. In some embodiments, the lithium niobate layer 12 may be from about 0.1λ to about 0.2λ thick or from about 0.05λ to about 0.30λ thick and the silicon dioxide layer 45 may be about from about 0.05λ to about 0.40λ thick, about 0.20λ thick, or between about 400 nm and about 700 nm thick.

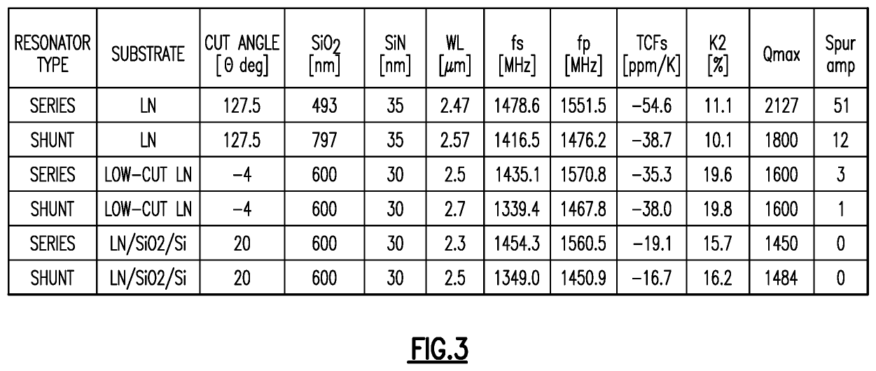

Simulations were performed for a number of different resonator structures including a bulk lithium niobate substrate as illustrated in FIG. 2A with a cut angle θ of 127.5 degrees (the “LN” substrate), a bulk lithium niobate substrate as illustrated in FIG. 2A with a cut angle θ of −4 degrees (the “Low-cut LN” substrate), and a multilayer piezoelectric substrate as illustrated in FIG. 2B with a lithium niobate cut angle θ of 20 degrees, a lithium niobate layer thickness of 0.1λ, and a buried silicon dioxide layer thickness of 0.2λ (the “LN/SiO2/Si” substrate). Resonators with operating frequencies appropriate as either series or shunt resonators in a ladder filter operating in the B32/n75 band were simulated for each substrate type. The simulated parameters of each of the resonators are illustrated in the table of FIG. 3 in which the SiO₂ and SiN parameters are the thicknesses of the layers of silicon dioxide and silicon nitride, respectively, on top of the substrates and IDT electrodes, WL is the wavelength of the acoustic wave generated by the resonator, fₛ and fₚ are the resonance and antiresonance frequencies, respectively, of the resonator, TCFs is the temperature coefficient of frequency at the resonance frequency of the resonators, k2 is the electromagnetic coupling coefficient of the resonators, Qmax is the quality factor at the resonance frequencies of the resonators, and Spur amp is the amplitude of a spurious signal observed in the admittance curves of the resonators just above the resonance frequency. Each of the resonators were simulated with IDT electrodes having a Mo layer thickness of 135 nm and an Al layer thickness of 180 nm. The resonators with the “LN/SiO2/Si” substrates exhibited better (closer to zero) TCFs than the resonators with the other substrate types and a k2 intermediate between the resonators with the other substrate types. The resonators with the “LN/SiO2/Si” substrates exhibited degraded Qmax as compared to the resonators with the other substrate types, but these Qmax values were still in a useful range.

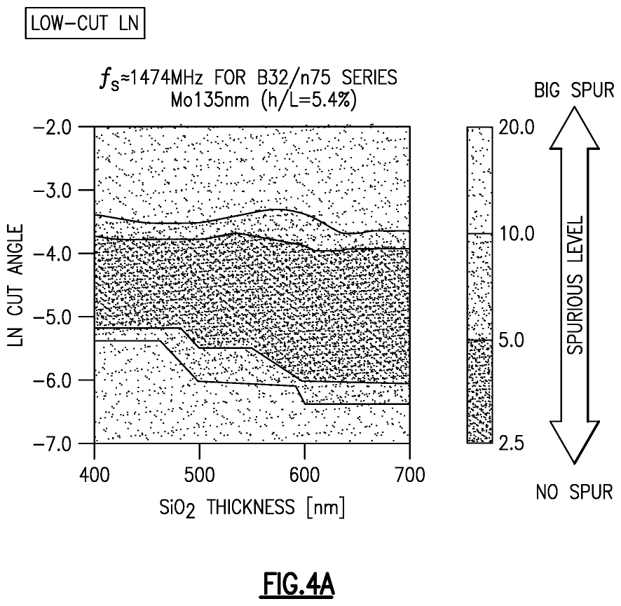

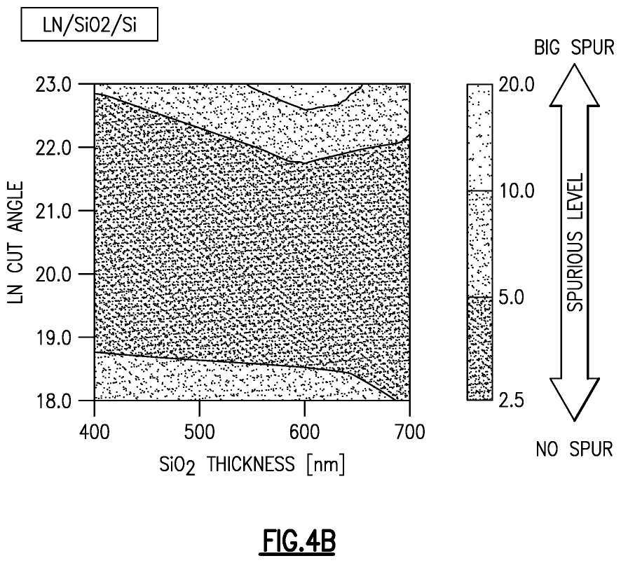

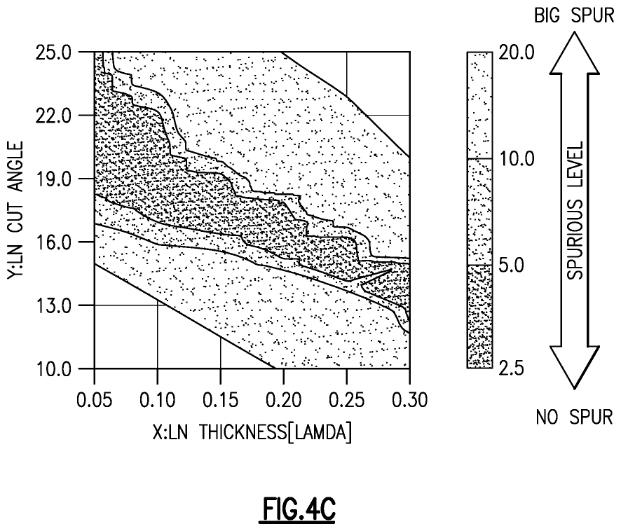

As illustrated in FIGS. 4A and 4B low levels of spurious signals were expected for resonators with the “Low-cut LN” substrates when the lithium niobate cut angle was set between about −4 degrees and −5 degrees while the thickness of the oxide layer 30 on top of the IDT electrodes was set at between 400 nm and 700 nm. The cut angle could be increased to −6 degrees and still maintain low spurious signals if the buried oxide thickness was set at between about 600 nm and about 700 nm. Low levels of spurious signals were expected with for resonators with the “LN/SiO2/Si” substrates when the lithium niobate cut angle was set between about 19 degrees and 22 degrees while the thickness of the oxide layer 30 on top of the IDT electrodes was set at between 400 nm and 700 nm. The cut angle could be decreased to 18 degrees and still maintain low spurious signal levels if the buried oxide thickness was set at close to 700 nm. The cut angle could be increased to about 23 degrees and still maintain low spurious signal levels if the buried oxide thickness was set at close to 400 nm or less. In further embodiments a cut angle of from about 12 degrees to about 25 degrees may provide acceptably low levels of spurious signals. FIG. 4C illustrates how the level of spurious signals may be dependent upon both the thickness and cut angle of the LN layer and that low levels of spurious signals may be achieved with cut angle of from about 12 degrees to about 25 degrees depending on the thickness of the LN layer.

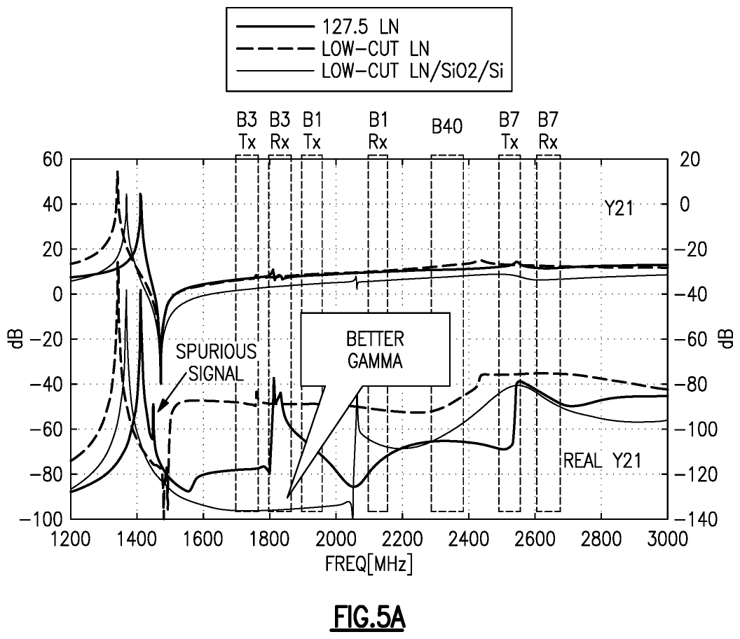

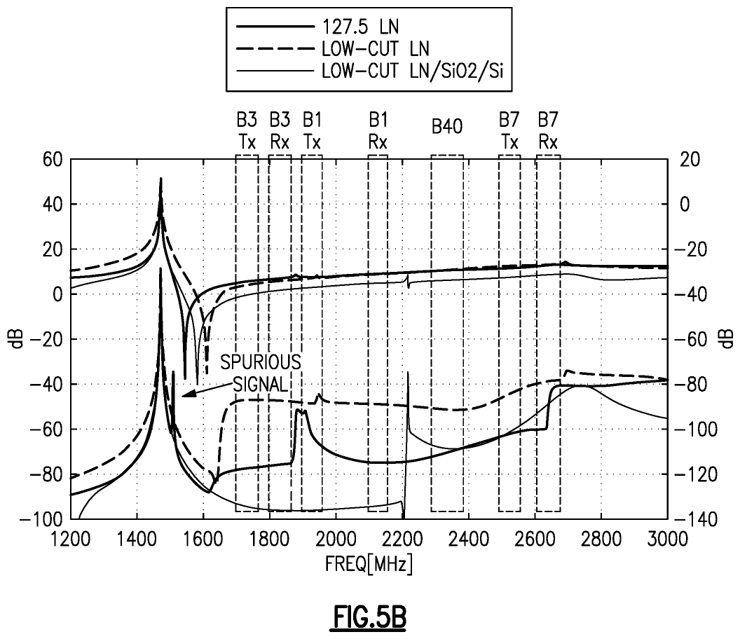

FIG. 5A illustrates results of simulation of the admittance (Y21) and real admittance (Real Y21) parameters versus frequency for the different shunt resonators. FIG. 5B illustrates results of simulation of the admittance (Y21) and real admittance (Real Y21) parameters versus frequency for the different series resonators. From FIGS. 5A and 5B it can be seen that the resonators with the “LN/SiO2/Si” substrates exhibited better gamma performance that the resonators with the other substrate types due to the lower Real Y21 levels above the resonance frequencies of the resonators as well as negligible spurious signals in the Y21 parameter just above the resonance frequency.

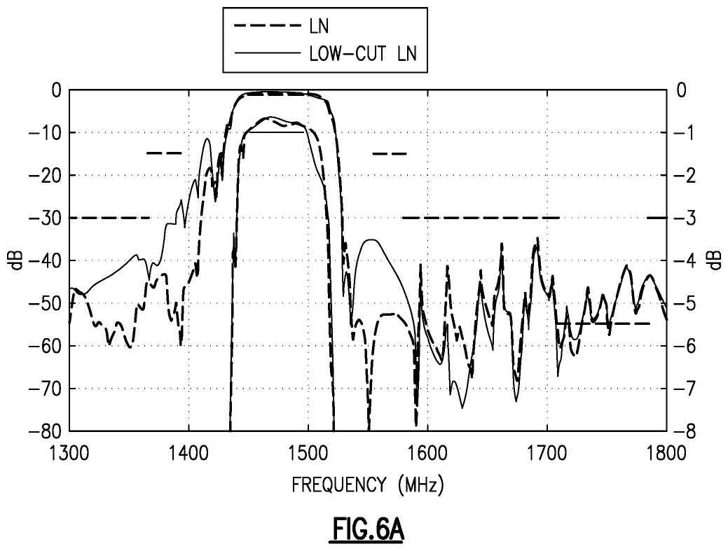

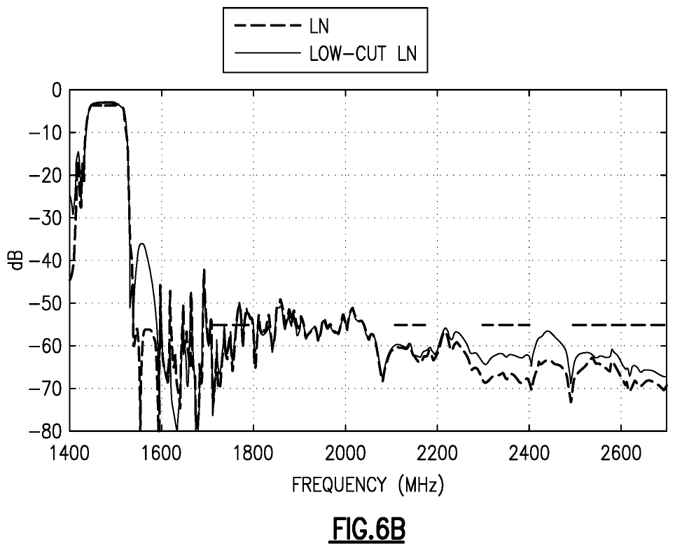

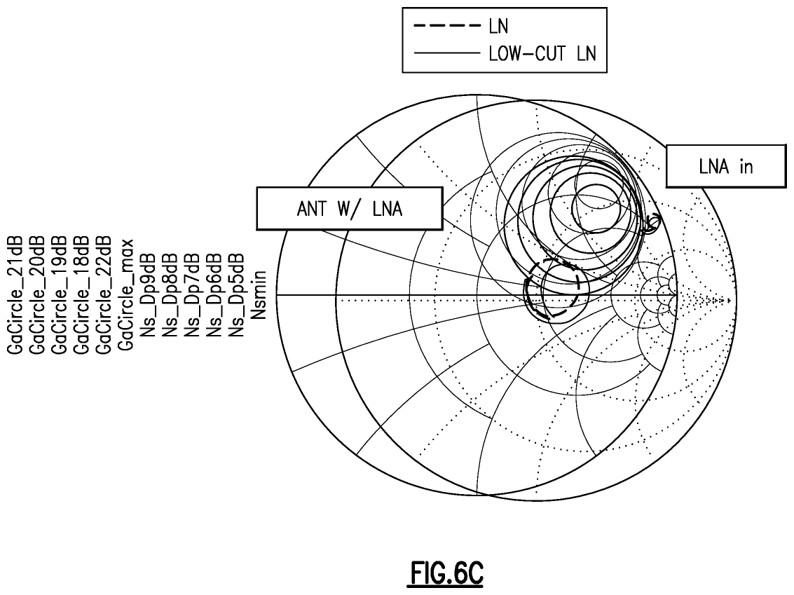

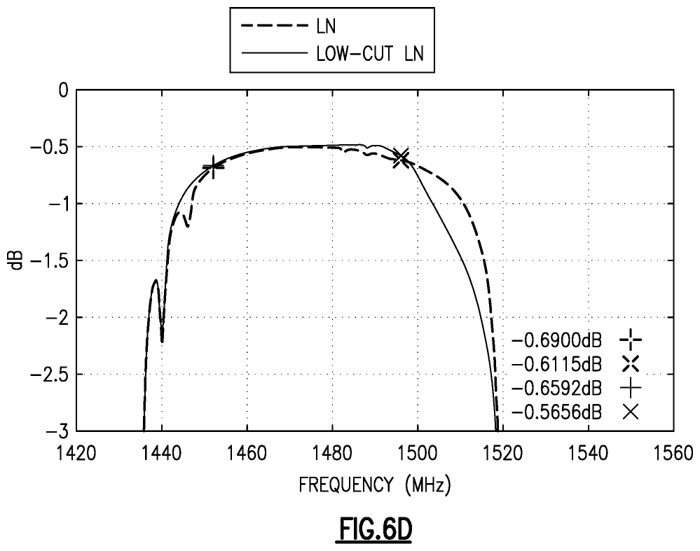

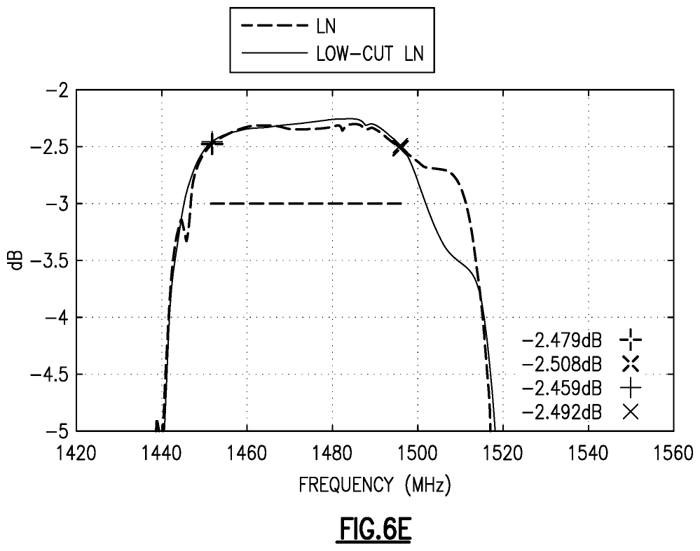

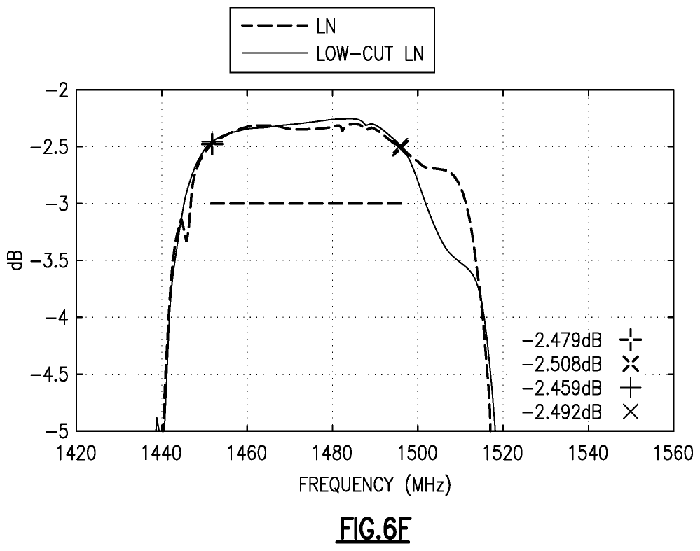

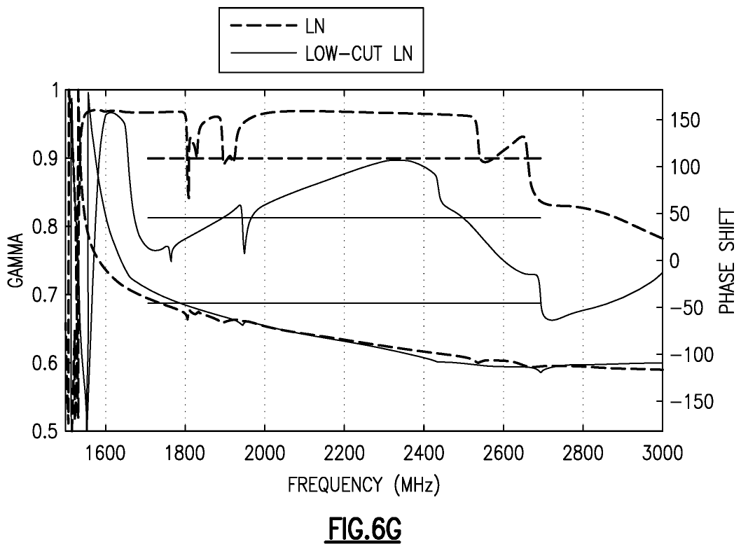

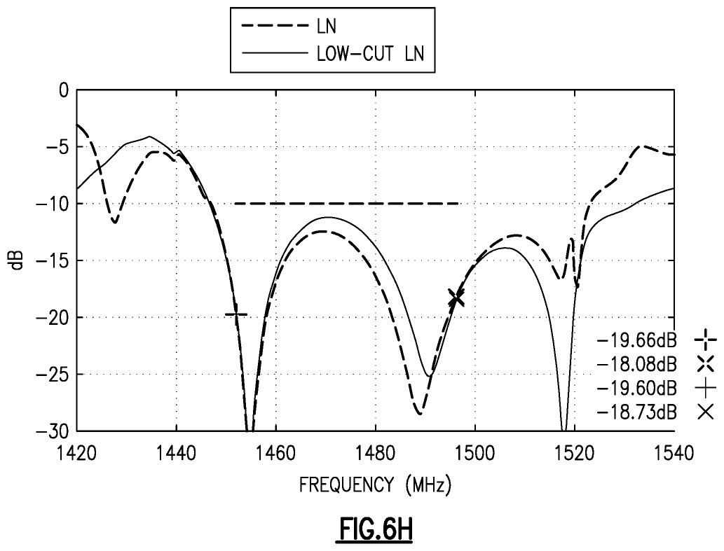

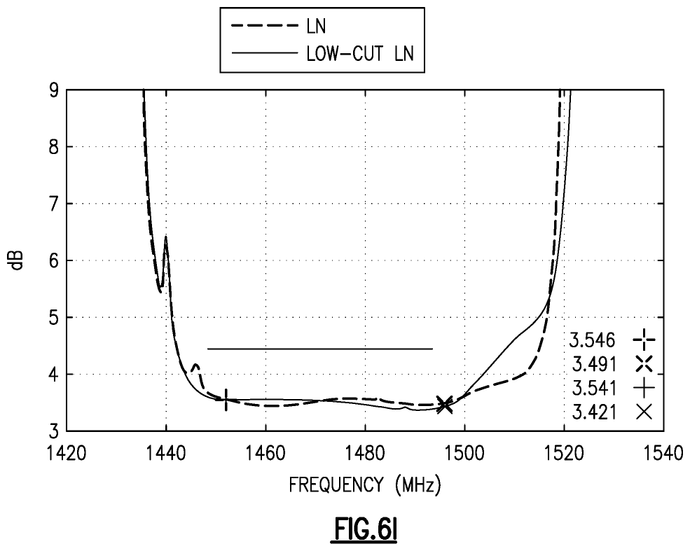

Simulations were performed to evaluate the performance characteristics of a ladder filter formed from the resonators with the characteristics indicated in FIG. 3. FIG. 6A illustrates attenuation versus frequency for unloaded ladder filters formed of resonators having the “LN” type substrates and having the “Low-cut LN” substrates. The filter formed of the resonators having the “Low-cut LN” substrates exhibited a less sharp upper edge of the passband as well as poorer attenuation both above and below the passband as compared to the filter formed of the resonators having the “LN” type substrates.

FIG. 6B illustrates carrier aggregation rejection versus frequency for loaded ladder filters connected to an antenna switch and formed of resonators having the “LN” type substrates and having the “Low-cut LN” substrates. The filter formed of the resonators having the “Low-cut LN” substrates exhibited poorer carrier aggregation rejection at frequencies above the passband as compared to the filter formed of the resonators having the “LN” type substrates.

FIG. 6C is a Smith chart of reflection characteristics of the antenna terminals (ANT w/LNA curves) and reflection characteristics of the filter output terminals (LNA in curves) for loaded ladder filters connected to an antenna switch and formed of resonators having the “LN” type substrates and having the “Low-cut LN” substrates.

FIG. 6D illustrates maximum gain versus frequency for unloaded ladder filters formed of resonators having the “LN” type substrates and having the “Low-cut LN” substrates. The filter formed of the resonators having the “Low-cut LN” substrates exhibited a less sharp upper edge of the passband as compared to the filter formed of the resonators having the “LN” type substrates.

FIG. 6E illustrates the passband for loaded ladder filters connected to an antenna switch and formed of resonators having the “LN” type substrates and having the “Low-cut LN” substrates. The filter formed of the resonators having the “Low-cut LN” substrates exhibited a less sharp upper edge of the passband as compared to the filter formed of the resonators having the “LN” type substrates.

FIG. 6F illustrates the passband for loaded ladder filters connected to an antenna switch and low noise amplifier and formed of resonators having the “LN” type substrates and having the “Low-cut LN” substrates. The filter formed of the resonators having the “Low-cut LN” substrates exhibited a less sharp upper edge of the passband as compared to the filter formed of the resonators having the “LN” type substrates.

FIG. 6G illustrates gamma and phase shift versus frequency for unloaded ladder filters formed of resonators having the “LN” type substrates and having the “Low-cut LN” substrates. The filter formed of the resonators having the “Low-cut LN” substrates exhibited better (lower) gamma as compared to the filter formed of the resonators having the “LN” type substrates. The phase shift performance as a function of frequency of the filters formed of the two resonator types was approximately equivalent.

FIG. 6H illustrates the S11 reflectance parameter versus frequency for loaded ladder filters connected to an antenna switch and low noise amplifier and formed of resonators having the “LN” type substrates and having the “Low-cut LN” substrates. The filter formed of the resonators having the “Low-cut LN” substrates exhibited higher reflectance in the middle of the passband as compared to the filter formed of the resonators having the “LN” type substrates.

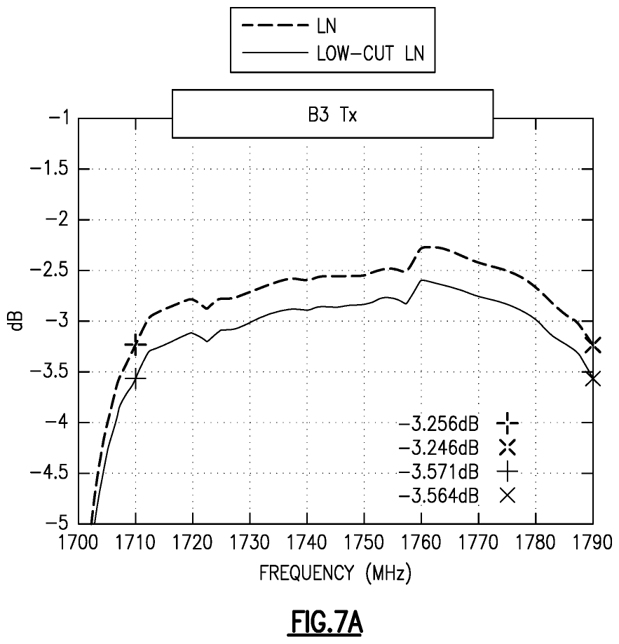

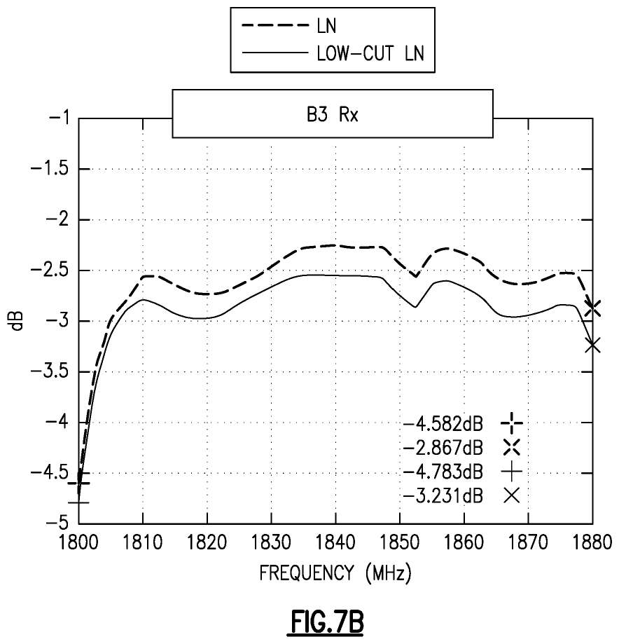

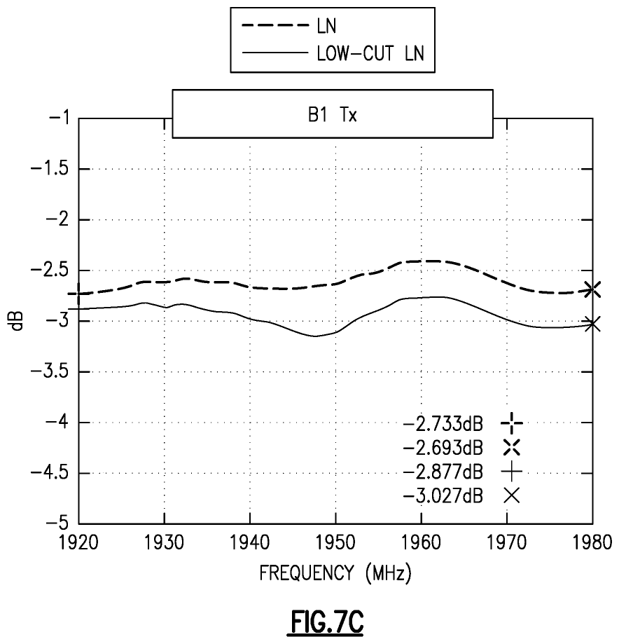

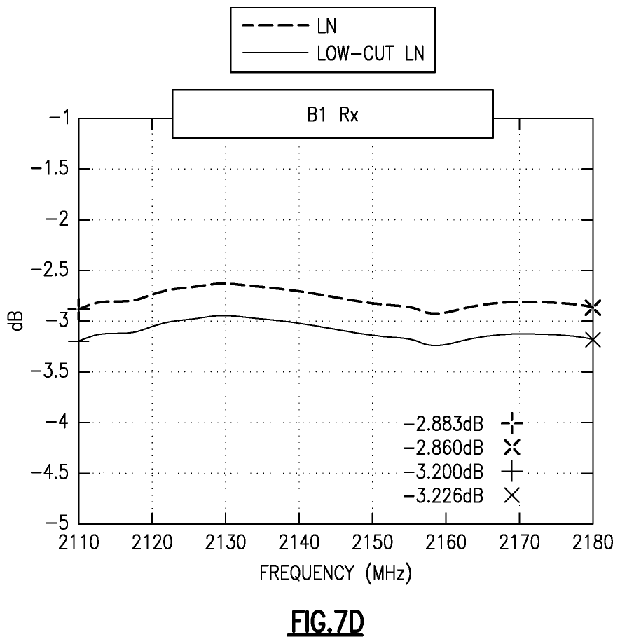

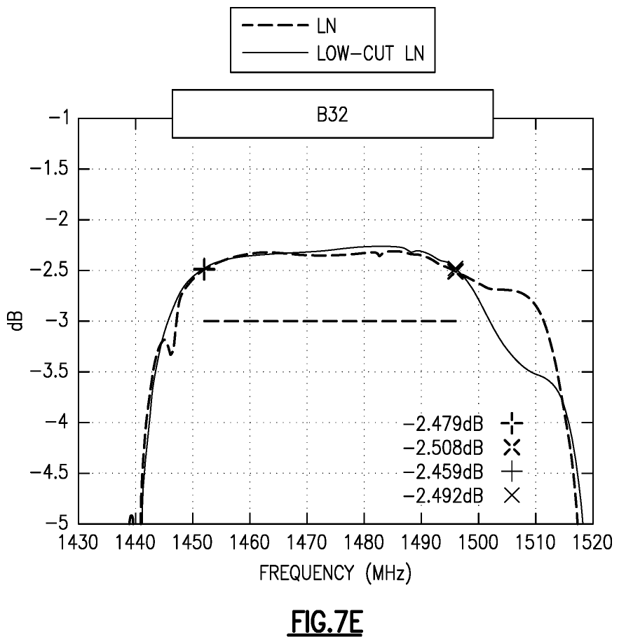

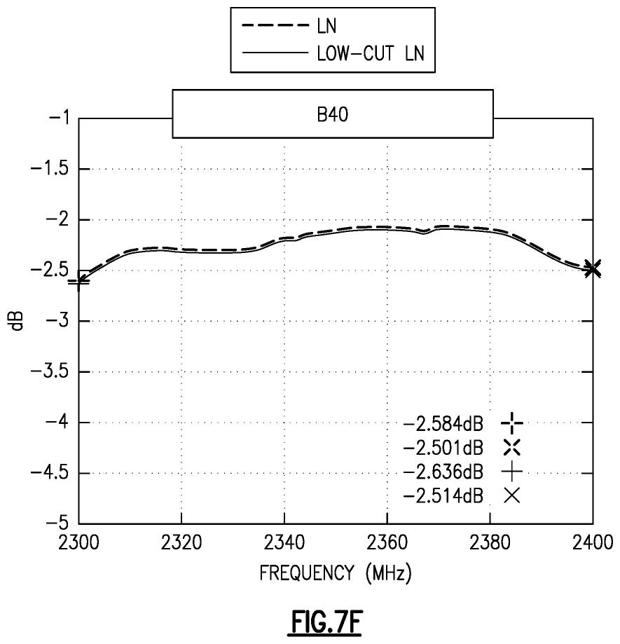

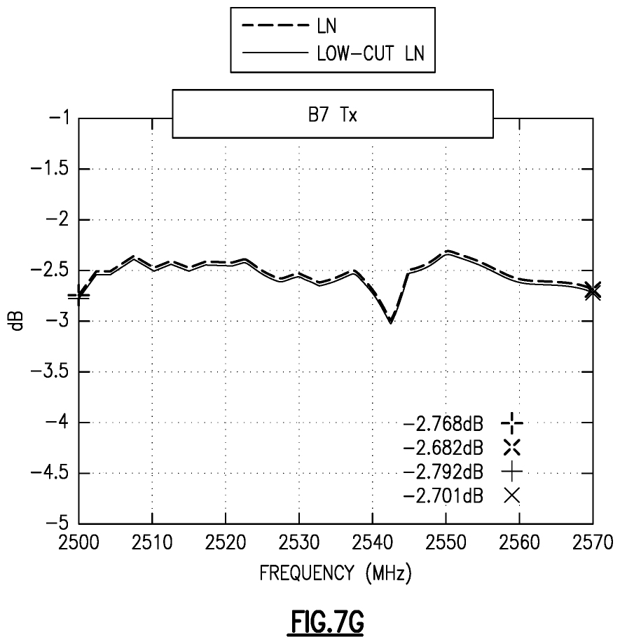

FIG. 6I illustrates versus frequency for unloaded ladder filters formed of resonators having the “LN” type substrates and having the “Low-cut LN” substrates. The noise figure is a parameter that indicates the degree of deterioration of the signal to noise ratio of the signal that has passed through the amplifier circuit. The smaller the noise figure, the better, because the noise is desirably as small as possible for the received signal. The filter formed of the resonators having the “Low-cut LN” substrates exhibited higher noise at the upper end of the passband as compared to the filter formed of the resonators having the “LN” type substrates. Simulations were performed to evaluate the loading loss characteristics versus frequency of a ladder filter formed from the resonators having the “LN” type substrates and having the “Low-cut LN” substrates for various bands. The bands for which loading loss was simulated included the B3 transmission band (FIG. 7A), the B3 reception band (FIG. 7B), the B1 transmission band (FIG. 7C), the B1 reception band (FIG. 7D), the B32 band (FIG. 7E), the B40 band (FIG. 7F), the B7 transmission band (FIG. 7G), and the B7 reception band (FIG. 7H). For each of the B3 transmission and reception bands and the B1 transmission and reception bands, the filter formed of the resonators having the “Low-cut LN” substrates exhibited greater (more negative) loading losses than the filter formed of the resonators having the “LN” type substrates. For the B32 band the filter formed of the resonators having the “Low-cut LN” substrates exhibited greater (more negative) loading losses at the upper end of the passband. Loading loss performance for the filters formed of the different resonator types was substantially equivalent for the B40 and B7 transmission and reception bands.

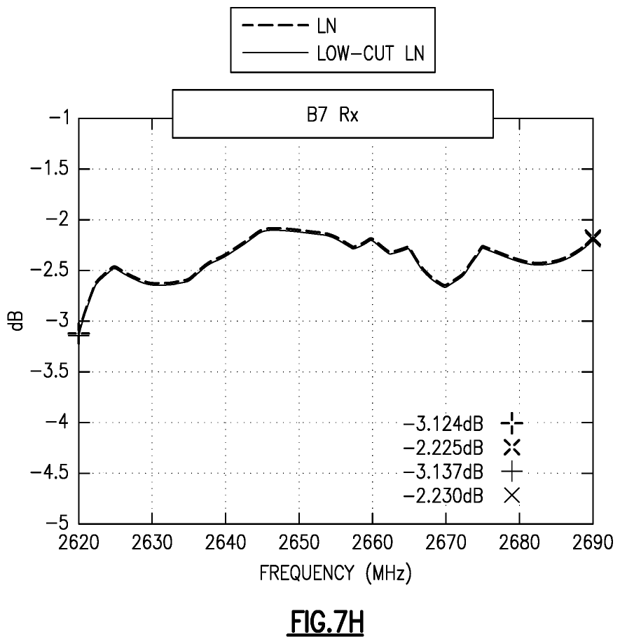

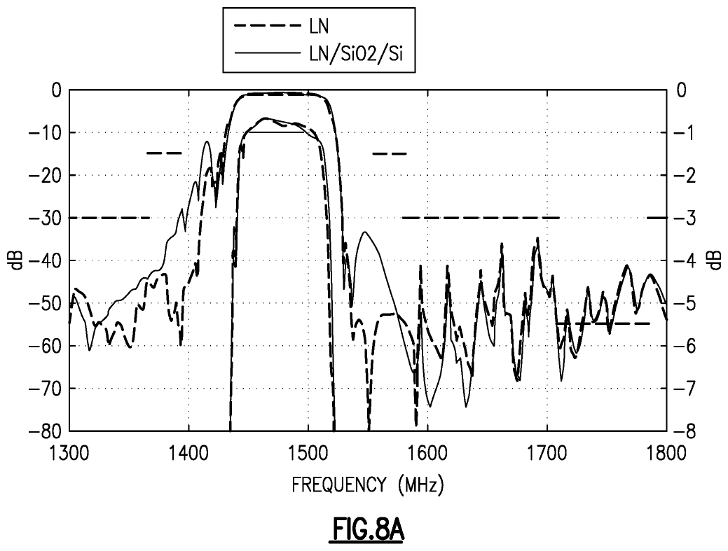

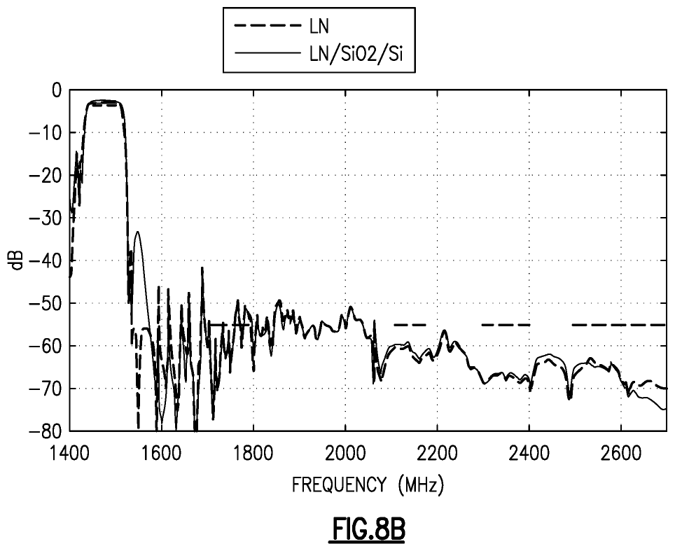

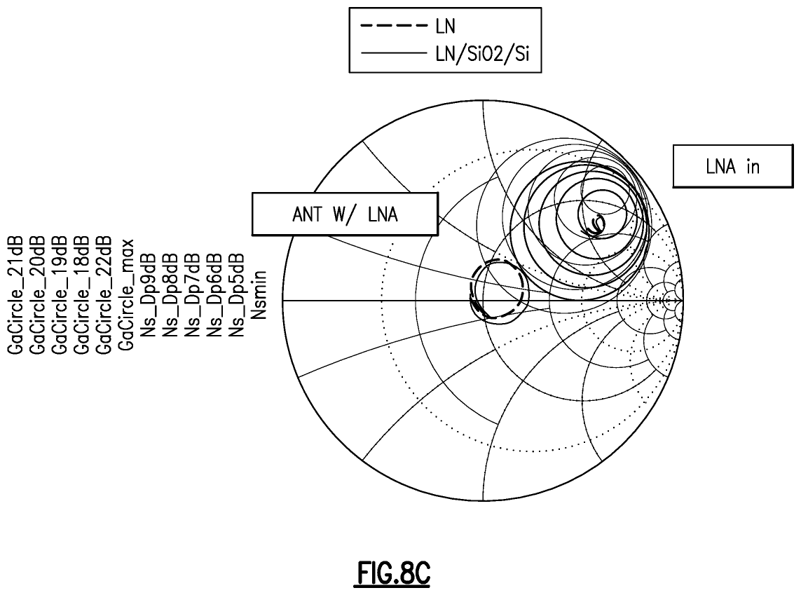

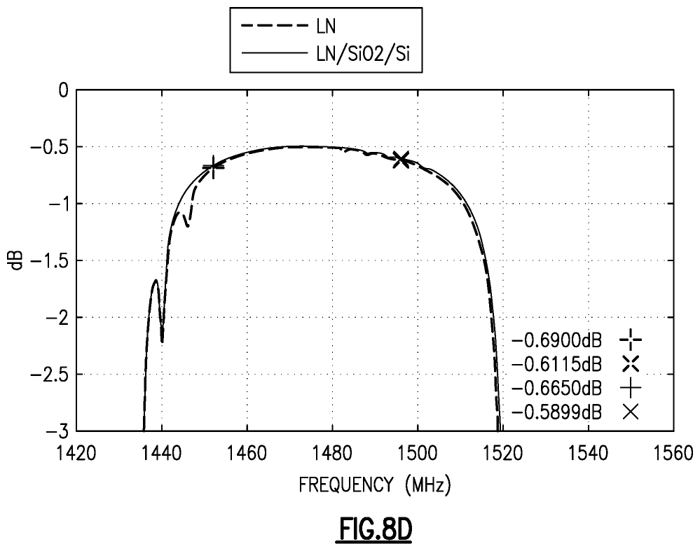

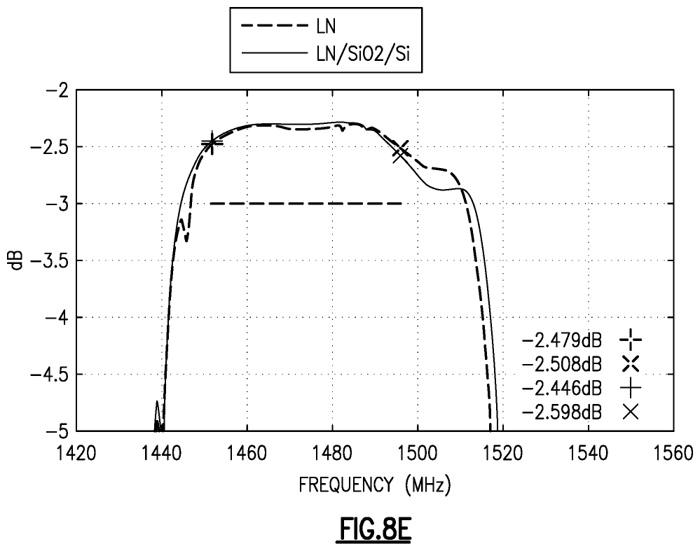

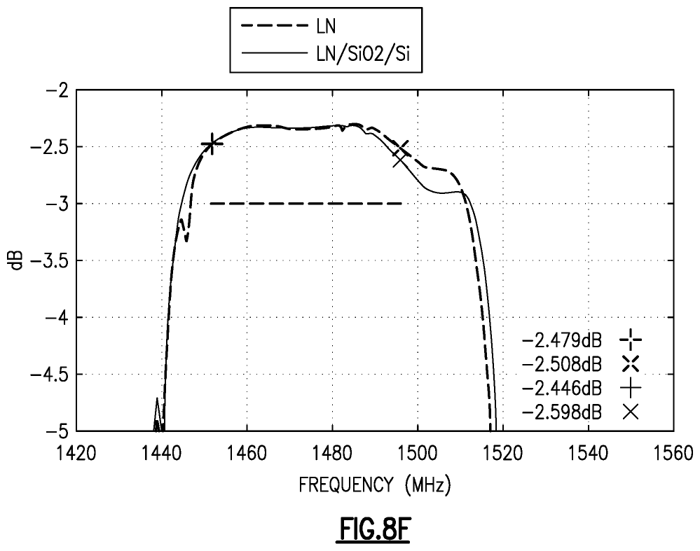

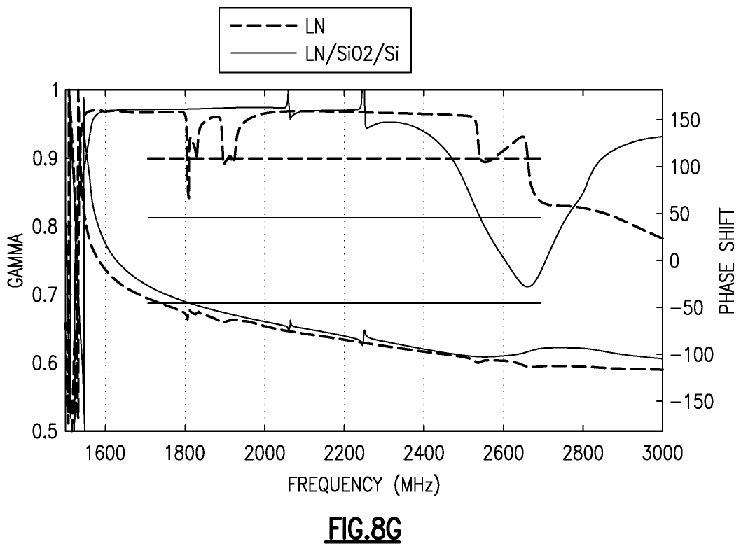

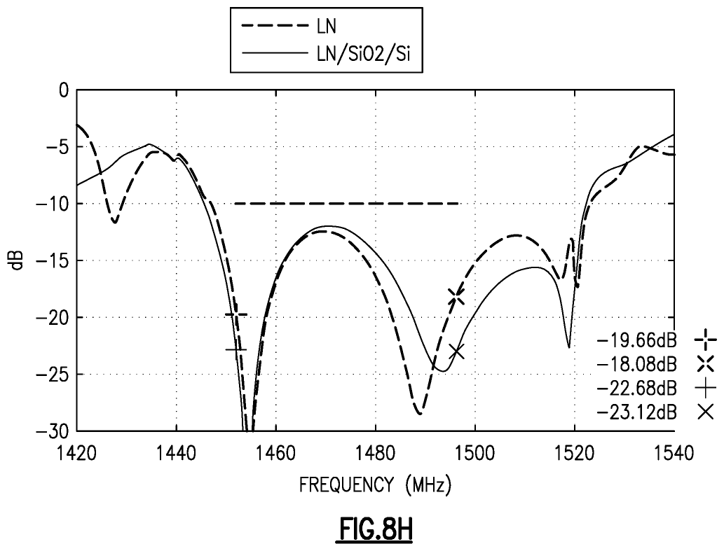

Simulations were performed to evaluate the performance characteristics of a ladder filter formed from the resonators with the “LN” type substrates and having the “LN/SiO2/Si” substrates. FIG. 8A illustrates attenuation versus frequency for unloaded ladder filters formed of resonators having the “LN” type substrates and having the “LN/SiO2/Si” substrates. The filter formed of the resonators having the “LN/SiO2/Si” substrates exhibited poorer rejection both immediately below and immediately above the passband as compared to the filter formed of the resonators having the “LN” type substrates, but within acceptable limits given the improved gamma and TCF provided by the “LN/SiO2/Si” type substrate.

FIG. 8B illustrates carrier aggregation rejection versus frequency for loaded ladder filters connected to an antenna switch and formed of resonators having the “LN” type substrates and having the “LN/SiO2/Si” substrates. The filter formed of the resonators having the “LN/SiO2/Si” substrates exhibited poorer carrier aggregation rejection at frequencies just above the passband as compared to the filter formed of the resonators having the “LN” type substrates, but within acceptable limits given the improved gamma and TCF provided by the “LN/SiO2/Si” type substrate.

FIG. 8C is a Smith chart of reflection characteristics of the antenna terminals (ANT w/LNA curves) and reflection characteristics of the filter output terminals (LNA in curves) for loaded ladder filters connected to an antenna switch and formed of resonators having the “LN” type substrates and having the “LN/SiO2/Si” substrates.

FIG. 8D illustrates maximum gain versus frequency for unloaded ladder filters formed of resonators having the “LN” type substrates and having the “LN/SiO2/Si” substrates. The filter formed of the resonators having the “LN” substrates exhibited a less sharp lower edge of the passband as compared to the filter formed of the resonators having the “LN/SiO2/Si” type substrates.

FIG. 8E illustrates the passband for loaded ladder filters connected to an antenna switch and formed of resonators having the “LN” type substrates and having the “LN/SiO2/Si” substrates. The filter formed of the resonators having the “LN/SiO2/Si” substrates exhibited a sharper lower edge of the passband but a less sharp upper edge of the passband as compared to the filter formed of the resonators having the “LN” type substrates, but within acceptable limits given the improved gamma and TCF provided by the “LN/SiO2/Si” type substrate.

FIG. 8F illustrates the passband for loaded ladder filters connected to an antenna switch and low noise amplifier and formed of resonators having the “LN” type substrates and having the “LN/SiO2/Si” substrates. The filter formed of the resonators having the “LN/SiO2/Si” substrates exhibited better performance at the upper and lower edges of the passband but worse performance in the middle of the passband as compared to the filter formed of the resonators having the “LN” type substrates, but within acceptable limits given the improved gamma and TCF provided by the “LN/SiO2/Si” type substrate.

FIG. 8G illustrates gamma and phase shift versus frequency for unloaded ladder filters formed of resonators having the “LN” type substrates and having the “LN/SiO2/Si” substrates. The filter formed of the resonators having the “LN/SiO2/Si” substrates exhibited better (lower) gamma as compared to the filter formed of the resonators having the “LN” type substrates at frequencies well above the passband, for example, above 2.3 GHZ, but worse (higher) gamma at frequencies between about 1.8 GHz and 2 GHz, but within acceptable limits. The phase shift performance as a function of frequency of the filters formed of the two resonator types was approximately equivalent.

FIG. 8H illustrates the S11 reflectance parameter versus frequency for loaded ladder filters connected to an antenna switch and low noise amplifier and formed of resonators having the “LN” type substrates and having the “LN/SiO2/Si” substrates. The filter formed of the resonators having the “LN/SiO2/Si” substrates exhibited higher reflectance in the lower half of the passband but lower reflectance in the upper half of the passband as compared to the filter formed of the resonators having the “LN” type substrates.

FIG. 8I illustrates noise figure versus frequency for unloaded ladder filters formed of resonators having the “LN” type substrates and having the “LN/SiO2/Si” substrates. The filter formed of the resonators having the “LN/SiO2/Si” substrates exhibited higher noise at the upper end of the passband but lower noise in a small frequency band at the lower end of the passband as compared to the filter formed of the resonators having the “LN” type substrates.

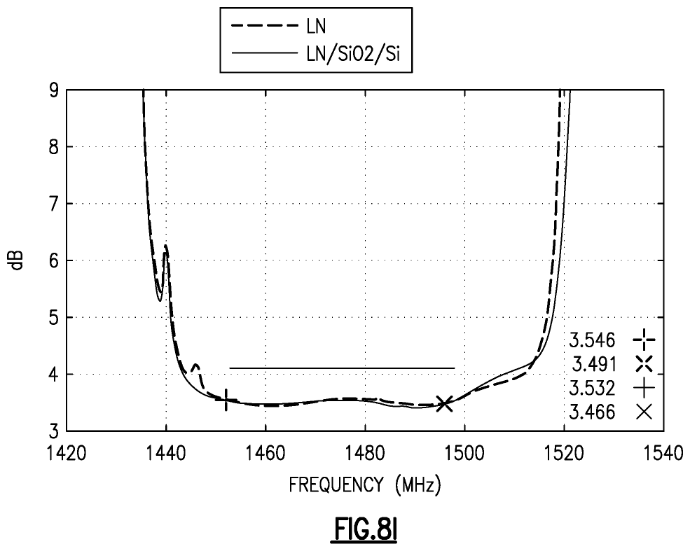

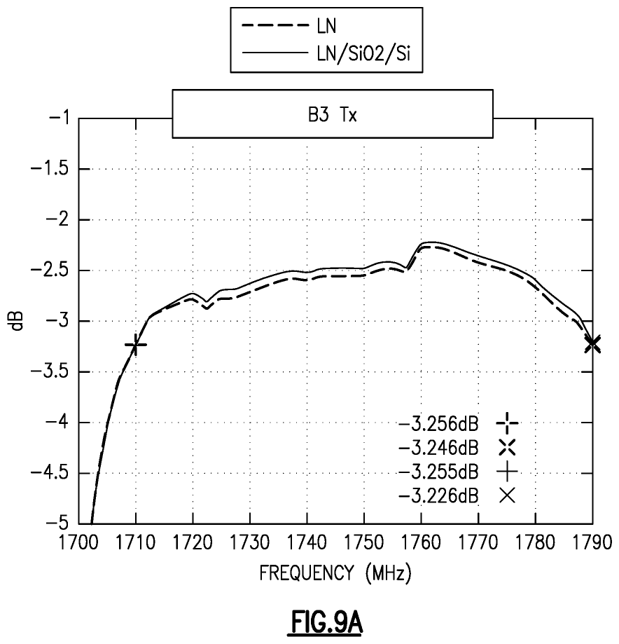

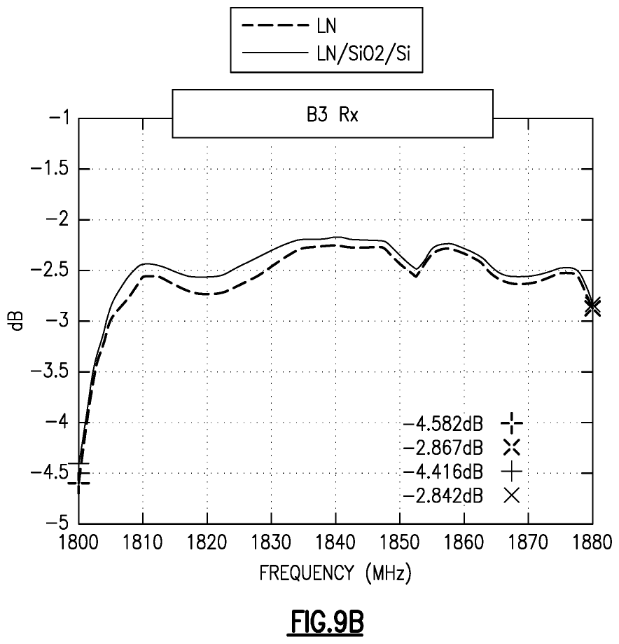

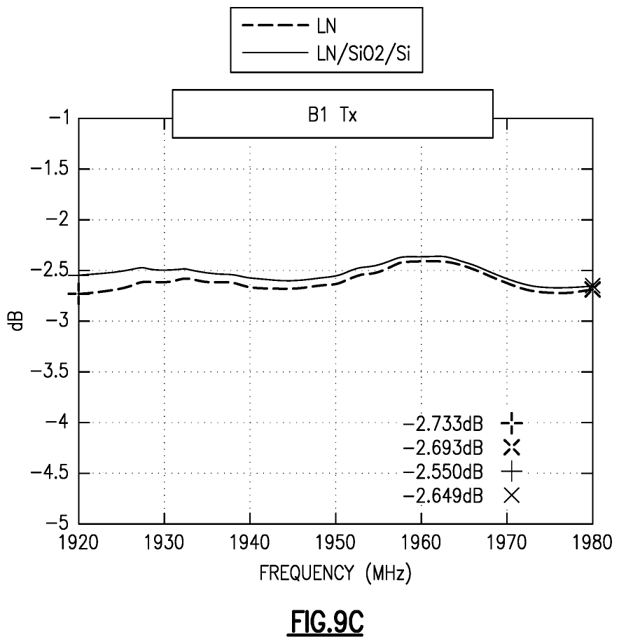

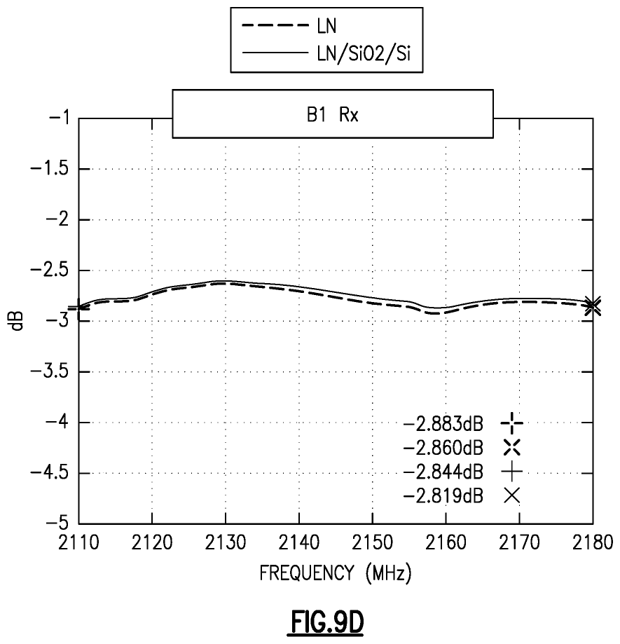

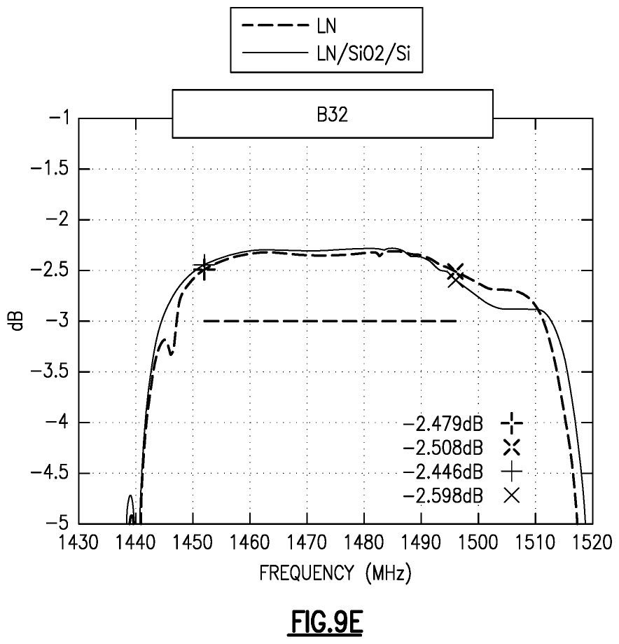

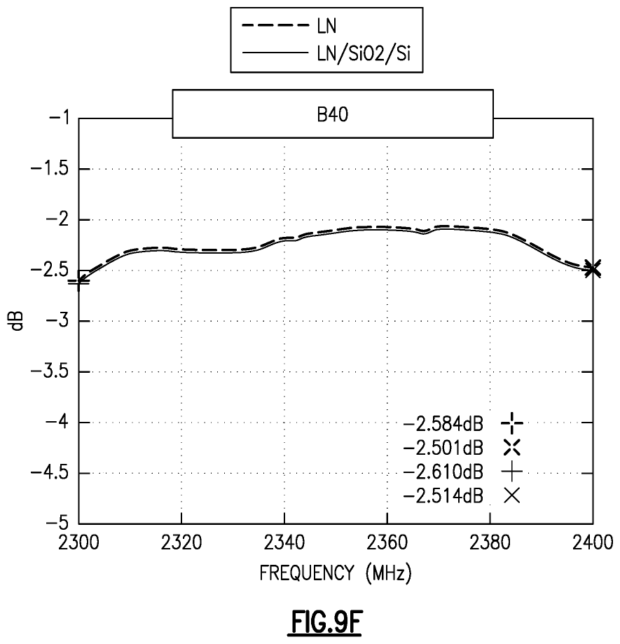

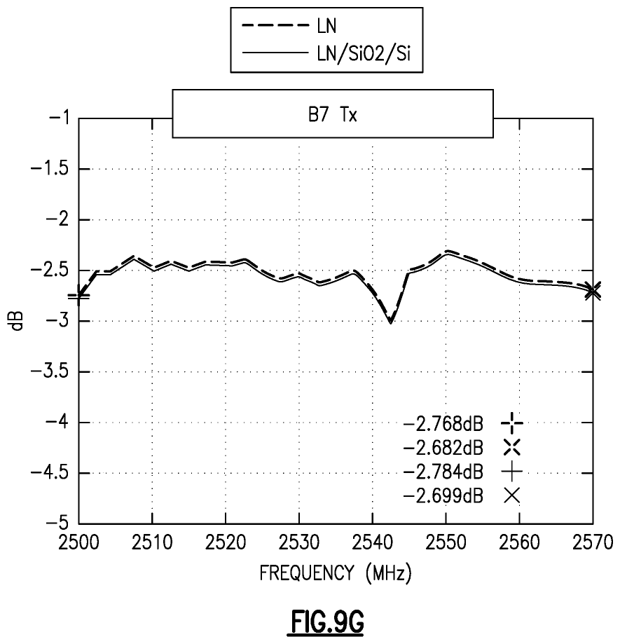

Simulations were performed to evaluate the loading loss characteristics versus frequency of a ladder filter formed from the resonators having the “LN” type substrates and having the “LN/SiO2/Si” substrates for various bands. The bands for which loading loss was simulated included the B3 transmission band (FIG. 9A), the B3 reception band (FIG. 9B), the B1 transmission band (FIG. 9C), the B1 reception band (FIG. 9D), the B32 band (FIG. 9E), the B40 band (FIG. 9F), the B7 transmission band (FIG. 9G), and the B7 reception band (FIG. 9H). For each of the B3 transmission and reception bands and the B1 transmission and reception bands, the filter formed of the resonators having the “LN/SiO2/Si” substrates exhibited lower (less negative) loading losses than the filter formed of the resonators having the “LN” type substrates. For the B32 band the filter formed of the resonators having the “LN/SiO2/Si” substrates exhibited greater (more negative) loading losses at the upper end of the passband. Loading loss performance for the filters formed of the different resonator types was substantially equivalent for the B40 and B7 transmission and reception bands.

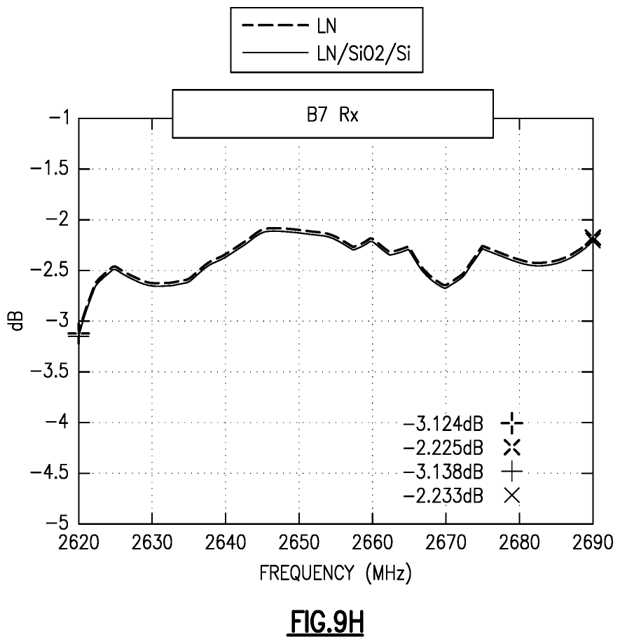

In some embodiments, multiple SAW resonators as disclosed herein may be combined into a filter, for example, an RF ladder filter schematically illustrated in FIG. 10 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

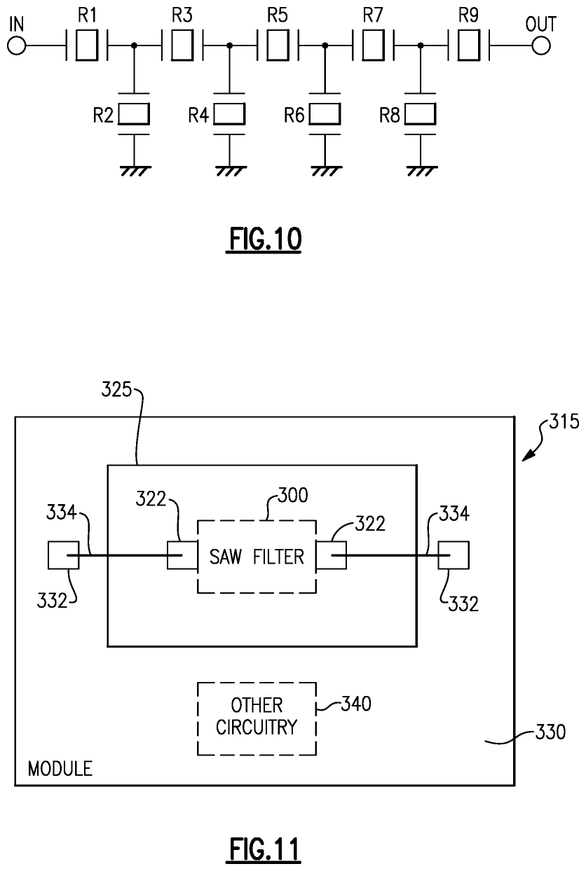

Examples of the SAW devices, e.g., SAW resonators discussed herein can be implemented in a variety of packaged modules. Some example packaged modules will now be discussed in which any suitable principles and advantages of the SAW devices discussed herein can be implemented. FIGS. 11, 12, and 13 are schematic block diagrams of illustrative packaged modules and devices according to certain embodiments.

As discussed above, surface acoustic wave resonators can be used in surface acoustic wave (SAW) RF filters. In turn, a SAW RF filter using one or more surface acoustic wave elements may be incorporated into and packaged as a module that may ultimately be used in an electronic device, such as a wireless communications device, for example. FIG. 11 is a block diagram illustrating one example of a module 315 including a SAW filter 300. The SAW filter 300 may be implemented on one or more die(s) 325 including one or more connection pads 322. For example, the SAW filter 300 may include a connection pad 322 that corresponds to an input contact for the SAW filter and another connection pad 322 that corresponds to an output contact for the SAW filter. The packaged module 315 includes a packaging substrate 330 that is configured to receive a plurality of components, including the die 325. A plurality of connection pads 332 can be disposed on the packaging substrate 330, and the various connection pads 322 of the SAW filter die 325 can be connected to the connection pads 332 on the packaging substrate 330 via electrical connectors 334, which can be solder bumps or wirebonds, for example, to allow for passing of various signals to and from the SAW filter 300. The module 315 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 315 can also include one or more packaging structures to, for example, provide protection and facilitate easier handling of the module 315. Such a packaging structure can include an overmold formed over the packaging substrate 330 and dimensioned to substantially encapsulate the various circuits and components thereon.

Various examples and embodiments of the SAW filter 300 can be used in a wide variety of electronic devices. For example, the SAW filter 300 can be used in an antenna duplexer, which itself can be incorporated into a variety of electronic devices, such as RF front-end modules and communication devices.

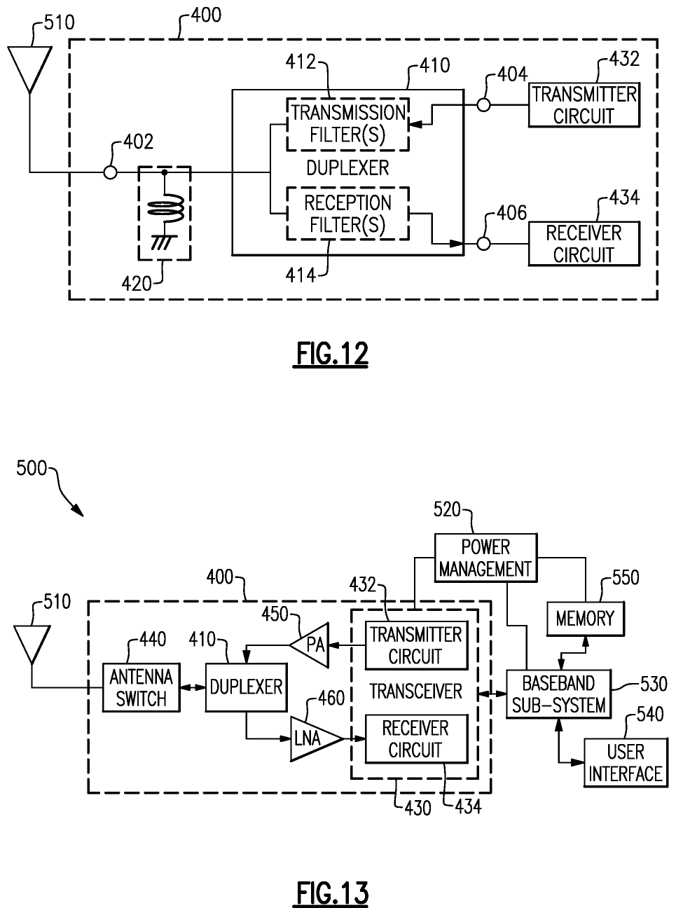

Referring to FIG. 12, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 300 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 12, however, in other embodiments these components may be integrated into a common transceiver circuit or module. As will be appreciated by those skilled in the art, the front-end module 400 may include other components that are not illustrated in FIG. 12 including, but not limited to, switches, electromagnetic couplers, amplifiers, processors, and the like.

FIG. 13 is a block diagram of one example of a wireless device 500 including the antenna duplexer 410 shown in FIG. 12. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 12. The front-end module 400 includes the duplexer 410, as discussed above. In the example shown in FIG. 13 the front-end module 400 further includes an antenna switch 440, which can be configured to switch between different frequency bands or modes, such as transmit and receive modes, for example. In the example illustrated in FIG. 13, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 13.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 13, the front-end module 400 may further include a low noise amplifier module 460, which amplifies received signals from the antenna 510 and provides the amplified signals to the receiver circuit 434 of the transceiver 430.

The wireless device 500 of FIG. 13 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave resonator comprising:
a multi-layer piezoelectric substrate including a carrier substrate, a layer of a first dielectric material disposed on a front side of the carrier substrate, and a layer of piezoelectric material disposed on a front side of the layer of the first dielectric material, the piezoelectric material having a cut angle θ of from about 12 degrees to about 25 degrees to suppress bulk leakage and improve gamma; and
interdigital transducer electrodes disposed on a front side of the layer of piezoelectric material.

2. The surface acoustic wave resonator of claim 1 further comprising a layer of a second dielectric material disposed on the layer of piezoelectric material and the interdigital transducer electrodes.

3. The surface acoustic wave resonator of claim 2 wherein the first dielectric material comprises silicon dioxide.

4. The surface acoustic wave resonator of claim 2 wherein the second dielectric material comprises silicon dioxide.

5. The surface acoustic wave resonator of claim 1 wherein the layer of piezoelectric material has a thickness of from about 0.1λ to about 0.2λ.

6. The surface acoustic wave resonator of claim 1 wherein the layer of the first dielectric material has a thickness of from about 0.05λ to about 0.40λ.

7. The surface acoustic wave resonator of claim 1 exhibiting a temperature coefficient of frequency at its resonant frequency of greater than about −19 ppm/° K.

8. The surface acoustic wave resonator of claim 1 exhibiting an electromagnetic coupling coefficient of at least about 15.5.

9. The surface acoustic wave resonator of claim 1 exhibiting a quality factor at its resonance frequency of at least about 1450.

10. The surface acoustic wave resonator of claim 1 wherein the layer of piezoelectric material is formed of lithium niobate.

11. A filter including the surface acoustic wave resonator of claim 1.

12. A radio frequency device module including the filter of claim 11.

13. A radio frequency device including the radio frequency device module of claim 12.

14. A method of forming a surface acoustic wave resonator, the method comprising:
forming interdigital transducer electrodes on a multi-layer piezoelectric substrate including a carrier substrate, a layer of a first dielectric material disposed on a front side of the carrier substrate, and a layer of lithium niobate disposed on a front side of the layer of the first dielectric material, the piezoelectric material having a cut angle θ of from about 12 degrees to about 25 degrees to suppress bulk leakage and improve gamma.

15. The method of claim 14 further comprising forming a layer of a second dielectric material on the interdigital transducer electrodes and the layer of piezoelectric material.

16. The method of claim 14 wherein the layer of the first dielectric material is formed with a thickness of from about 0.1λ to about 0.2λ.

17. The method of claim 14 wherein the layer of piezoelectric material is formed with a thickness of from about 0.05λ to about 0.30λ

18. The method of claim 13 further comprising forming a radio frequency filter including the surface acoustic wave resonator of claim 13.

19. The method of claim 18 further comprising forming a radio frequency device module including the radio frequency filter of claim 18.

20. The method of claim 19 further comprising forming a radio frequency electronic device including the radio frequency device module of claim 19.
